(19) United States
(12) Patent Application Publication
(10) Pub. No.: US 2021/0343983 A1
(43) Pub. Date: Nov. 4, 2021

(54) LIGHT EMITTING PANEL AND DISPLAY DEVICE

(71) Applicant: WUHAN CHINA STAR OPTOELECTRONICS SEMICONDUCTOR DISPLAY TECHNOLOGY CO., LTD., WUHAN (CN)

(72) Inventors: XIONG LI, WUHAN (CN); SHUNYING LI, WUHAN (CN)

(21) Appl. No.: 16/614,056

(22) PCT Filed: Sep. 10, 2019
(86) PCT No.: PCT/CN2019/105154

§ 371 Date: Nov. 15, 2019

(30) Foreign Application Priority Data
Jun. 19, 2019 (CN) 201910533342.2

(51) Int. Cl. H01L 51/52

(52) U.S. Cl. CPC H01L 51/5253

(57) ABSTRACT

A light emitting panel and a display device are disclosed. The light emitting panel including: a substrate and an insulating layer disposed on the substrate; a crack stop including a blocking portion and an extension portion, wherein the blocking portion disposed on at least one end of the insulating layer, and the extension portion extended onto the substrate; and an encapsulation layer covered the crack stop and the substrate, wherein at least one groove is disposed on the blocking portion. Thereby, a crack generated by cutting the light emitting panel is prevented from extending to a display area, and a yield of the light emitting panel is increased.

### BACKGROUND OF DISCLOSURE

### 1. Field of Disclosure

The present disclosure is related to the field of display techniques, and in particular to a light emitting panel and a display device.

### 2. Description of Related Art

In recent years, organic light emitting diodes (OLEDs) have gradually replaced thin film transistor liquid crystal displays (TFT-LCDs) due to their advantages, such as wide color gamut, high contrast ratio, wide viewing angles, fast response rates, lightweight, etc. In mobile phones, watches, and other applications, with the consumer's preference for big screens, a screen ratio of the screen is getting higher and higher.

In related art, one method for increasing the screen ratio is to design a narrower border. One of the limiting factors for the border is the presence of mask shadow when encapsulating the light panel. When the light emitting panel is cut, a crack is generated, and the crack will extend along the mask shadow to a display area, causing the encapsulation layer to fail, and affecting quality of the light emitting panel.

Therefore, the prior art has drawbacks and needs to improve urgently.

### SUMMARY

A light emitting panel and a display device are provided in the embodiment of the present disclosure, it can prevent the crack generated by cutting the light emitting panel from extending to the display area, thereby improving a yield rate of the light emitting panel.

In a first aspect, a light emitting panel is provided in an embodiment of the present disclosure, including:

a substrate and an insulating layer disposed on the substrate;

a crack stop including a blocking portion and an extension portion, wherein the blocking portion is disposed on at least one end of the insulating layer, and the extension portion is extended onto the substrate;

an encapsulation layer covered the crack stop and the substrate; wherein at least one groove is disposed on the blocking portion.

In the light emitting panel described in the present disclosure, the groove includes an opening portion and an inner cavity extending from the opening portion toward an inside of the blocking portion.

In the light emitting panel described in the present disclosure, a bottom of the inner cavity has at least one included angle and an angle of the included angle is 60°-120°.

In the light emitting panel described in the present disclosure, a concave-convex structure is disposed on a sidewall of the inner cavity, and a cross-sectional shape of the concave-convex structure is wavy or jagged.

In the light emitting panel described in the present disclosure, a length of a horizontal opening of the opening portion is greater than 5 μm.

In the light emitting panel described in the present disclosure, a thickness of the encapsulation layer disposed on the extension portion is greater than a thickness of the encapsulation layer disposed on the sidewall of the groove.

In the light emitting panel described in the present disclosure, a cross-sectional shape of the groove is any one of a square, a triangle and a trapezoid.

In the light emitting panel described in the present disclosure, a plurality of grooves are disposed on the blocking portion, the plurality of grooves are spaced apart on the blocking portion.

In the light emitting panel described in the present disclosure, a retaining wall structure is further disposed on the insulating layer, the retaining wall structure is adjacent to the crack stop, and the encapsulating layer is covered the retaining wall structure.

In a second aspect, a display device is provided in the embodiment of the present disclosure, including: a housing and a light emitting panel, the light emitting panel is disposed on the housing, the light emitting panel including:

a substrate and an insulating layer disposed on the substrate;

a crack stop including a blocking portion and an extension portion, wherein the blocking portion is disposed on at least one end of the insulating layer, and the extension portion is extended onto the substrate;

an encapsulation layer covered the crack stop and the substrate; wherein at least one groove is disposed on the blocking portion.

In the display device described in the present disclosure, the groove includes an opening portion and an inner cavity extending from the opening portion toward an inside of the blocking portion.

In the display device described in the present disclosure, the inner cavity has at least one included angle and an angle of the included angle is 60°-120°.

In the display device described in the present disclosure, a concave-convex structure is disposed on a sidewall of the inner cavity, and a cross-sectional shape of the concave-convex structure is wavy or jagged.

In the display device described in the present disclosure, a length of a horizontal opening of the opening portion is greater than 5 μm.

In the display device described in the present disclosure, a thickness of the encapsulation layer disposed on the extension portion is greater than a thickness of the encapsulation layer disposed on the sidewall of the groove.

In the display device described in the present disclosure, a cross-sectional shape of the groove is any one of a square, a triangle and a trapezoid.

In the display device described in the present disclosure, a plurality of grooves are disposed on the blocking portion, the plurality of grooves are spaced apart on the blocking portion.

In the display device described in the present disclosure, a retaining wall structure is further disposed on the insulating layer, the retaining wall structure is adjacent to the crack stop, and the encapsulating layer is covered the retaining wall structure.

In a third aspect, a light emitting panel is provided in the embodiment of the present disclosure provides, including:

a substrate and an insulating layer disposed on the substrate;

a crack stop including a blocking portion and an extension portion, wherein the blocking portion is disposed on at least one end of the insulating layer, and the extension portion is extended onto the substrate;

an encapsulation layer covered the crack stop and the substrate; wherein

at least one groove is disposed on the blocking portion, and the groove includes an opening portion and an inner cavity extending from the opening portion toward an inside of the blocking portion, a retaining wall structure is further disposed on the insulating layer, the retaining wall structure is adjacent to the crack stop, and the encapsulating layer is covered the retaining wall structure.

In the light emitting panel described in the present disclosure, a bottom of the inner cavity has at least one included angle and an angle of the included angle is 60°-120°, a length of a horizontal opening of the opening portion is greater than 5 μm

A light emitting panel is provided in the embodiment of the present disclosure, including: a substrate and an insulating layer disposed on the substrate; a crack stop including a blocking portion and an extension portion, wherein the blocking portion is disposed on at least one end of the insulating layer, and the extension portion is extended onto the substrate; an encapsulation layer covered the crack stop and the substrate; wherein at least one groove is disposed on the blocking portion. Therefore, the crack generated by cutting the light emitting panel is prevented from extending to the display area, and the yield rate of the light emitting panel is improved.

### BRIEF DESCRIPTION OF DRAWINGS

In order to clearly illustrate the technical solutions in the embodiments of the present disclosure, the drawings used in the description of the embodiments will be briefly introduced below. Obviously, the drawings in the following description are only some embodiments of the disclosure. Other drawings can also be obtained from those skilled in the art based on these drawings without paying any inventive effort.

FIG. 1 is a schematic view of a structure of a display device according to an embodiment of the present disclosure.

FIG. 2 is a schematic view of a structure of a light emitting panel according to the embodiment of the present disclosure.

FIG. 3 is a schematic view of a first structure of a crack stop of the light emitting panel according to an embodiment of the present disclosure.

FIG. 4 is a schematic view of a second structure of a crack stop of the light emitting panel according to an embodiment of the present disclosure.

FIG. 5 is a schematic view of a third structure of a crack stop of the light emitting panel according to an embodiment of the present disclosure.

### DETAILED DESCRIPTION OF EMBODIMENTS

The technical solutions in the embodiments of the present disclosure are clearly and completely described in the following description, which is combined with the drawings in the embodiments of the present disclosure. Obviously, the described embodiments are only a part of the embodiments of the present disclosure, not all embodiments. Based on the embodiments in the present disclosure, other embodiments obtained by those skilled in the art without paying any inventive effort are within the scope of the present disclosure.

In the prior art, in the already-published organic light emitting diodes (OLEDs), the border is about 1.1 mm at the narrowest, and one of the factors limiting border is a presence of mask shadows in chemical vapor deposition (CVD). A distance from a film thickness stable region of a CVD deposited encapsulation layer to a shadow edge is about 200 μm. In order to prevent the CVD shadow film or a thicker region of CVD shadow from entering a cutting line, and causing a crack of the encapsulated CVD film layer extends toward the display region when cutting a sliver, thereby reducing reliability of the package. The distance from the edge of a uniform zone of a film thickness of a border zone packaging layer to the cutting line must be large enough. To this end, some designs have been added to a crack stop design to prevent the crack from extending toward the display area. The crack will continue to extend along the crack stop into the shaped cutting line, causing the encapsulation layer to fail.

A display device is provided in the embodiment of the present disclosure, includes a housing and a light emitting panel, the light emitting panel is disposed on the housing, the light emitting panel including:

a substrate and an insulating layer disposed on the substrate;

a crack stop including a blocking portion and an extension portion, the blocking portion disposed on at least one end of the insulating layer, the extension portion extended onto the substrate;

an encapsulation layer covered the crack stop and the substrate; wherein at least one groove is disposed on the blocking portion.

Wherein, the groove includes an opening portion and an inner cavity extending from the opening portion toward an inside of the blocking portion.

Wherein, a bottom of the inner cavity has at least one included angle and an angle of the included angle is 60°-120°.

Wherein, a concave-convex structure is disposed on a sidewall of the inner cavity, and a cross-sectional shape of the concave-convex structure is wavy or jagged.

Wherein, a length of a horizontal opening of the opening portion is greater than 5 μm.

Wherein, a thickness of the encapsulation layer disposed on the extension portion is greater than a thickness of the encapsulation layer disposed on the sidewall of the groove

Wherein, a cross-sectional shape of the groove is any one of a square, a triangle and a trapezoid.

Wherein, a plurality of grooves are disposed on the blocking portion, the plurality of grooves are spaced apart on the blocking portion.

Wherein, a retaining wall structure is further disposed on the insulating layer, the retaining wall structure is adjacent to the crack stop, and the encapsulating layer is covered the retaining wall structure.

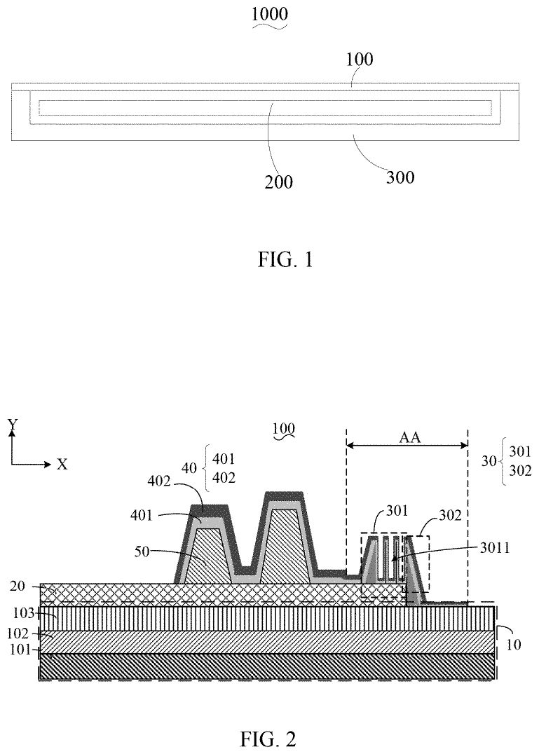

Please refer to FIG. 1, which is a schematic view of a structure of a display device 1000 according to an embodiment of the present disclosure. The display device 1000 may include a light emitting panel 100, a control circuit 200, and a housing 300. It should be noted that the display device 1000 shown in FIG. 1 is not limited to the above, and may further include other components, such as a camera, an antenna structure, a pattern unlocking module, and the like.

Wherein, the light emitting panel is disposed on the housing 300.

In some embodiments, the light emitting panel 100 may be fixed on the housing 300, and the light emitting panel 100 and the housing 300 form a confined space to accommodate a control circuit 200 and the like.

In some embodiments, the housing 300 may be made of a flexible material, such as a plastic housing or a silicon housing, and the like.

Wherein, the control circuit 200 is mounted in the housing 300. The control circuit 200 may be a main board of the display device 1000. The control circuit 200 may be integrated with one, two or more functional components such as a battery, an antenna structure, a microphone, a speaker, a headphone interface, a universal serial bus interface, a camera, a distance sensor, an ambient light sensor, a receiver, and a processor.

Wherein, the light emitting panel 100 is mounted in the housing 300. At the same time, the light emitting panel 100 is electrically connected to the control circuit 200 to form a display surface of the display device 100. The light emitting panel 100 may include a display area and a non-display area. The display area may be used to display a screen of the display device 100 or for a user to perform touch manipulation or the like. The non-display area may be used to arrange various functional components.

Please refer to FIG. 2, which is a schematic view of a structure of a light emitting panel 100 according to an embodiment of the present disclosure. The light emitting panel 100, including:

a substrate 10 and an insulating layer 20 disposed on the substrate 10;

a crack stop 30 including a blocking portion 301 and an extension portion 302, wherein the blocking portion 301 is disposed on at least one end of the insulating layer 20, and the extension portion 302 is extended onto the substrate 10;

an encapsulation layer 40 covered the crack stop 30 and the substrate 10;

wherein at least one groove 3011 is disposed on the blocking portion 301.

It can be understood that the AA area herein is a CVD shadow area, the cutting line is at a contact point of the crack stop 30 and the substrate 10. When the light emitting panel 100 is cut, the generated crack will extend along an upper surface of the crack stop 30 toward a negative half axis of an X-axis. At least one groove 3011 is disposed on the blocking portion 301 of the crack stop 30. The structure of the groove 3011 makes the encapsulation layer 40 deposited by the CVD to be deposited with the shape of the groove 3011, which causes the presence of a plurality of extended inflection points when the crack extends over the encapsulation layer 40. These inflection points are top of the crack stop 30, for example (an intersection of the blocking portion 301 and the extension portion 302). Therefore, when the crack extends to the top of the crack stop 30, the crack will automatically be broken due to a stress defect point or a stress defect area, and the crack is difficult to continue to extend.

Specifically, the crack stop 30 herein may be composed of an organic planarization layer (PLN); the encapsulation layer 40 is composed of a first inorganic encapsulation layer 401 and a second inorganic encapsulation layer 402, the second inorganic encapsulation layer 402 is covered on the first inorganic encapsulation layer 401, and an organic encapsulation layer (not shown) is further disposed between the first inorganic encapsulation layer 401 and the second inorganic encapsulation layer 402; the substrate 10 may be a flexible substrate.

A light emitting panel 100 is provided in the embodiment of the present disclosure, including: a substrate 10 and an insulating layer 20 disposed on the substrate 10; a crack stop 30 including a blocking portion 301 and an extension portion 302, wherein the blocking portion 301 is disposed on at least one end of the insulating layer 20, and the extension portion 302 is extended onto the substrate 10; an encapsulation layer 40 covered the crack stop 30 and the substrate 10; wherein at least one groove 3011 is disposed on the blocking portion 301. Therefore, the crack generated by cutting the light emitting panel 100 is prevented from extending to the display area, and the yield rate of the light emitting panel is improved.

In some embodiments, the substrate 10 including: a flexible layer 101, an MB layer 102, and a buffer layer 103 which are stacked from bottom to top sequentially, and the insulating layer 20 is disposed on the buffer layer 103.

Wherein, the MB layer 102 may include a G1 layer, a G2 layer, and an inter layer dielectric (ILD), (not shown in the drawings).

In some embodiments, a retaining wall structure 50 is further disposed on the insulating layer 20, the retaining wall structure 50 is adjacent to the crack stop 30, and the encapsulating layer 40 is covered the retaining wall structure 50.

Wherein, the retaining wall structure 50 is generally used to block the organic encapsulating layer in the encapsulating layer 40, and the display area is in the direction of the negative half axis of the retaining wall structure 50 to the X-axis.

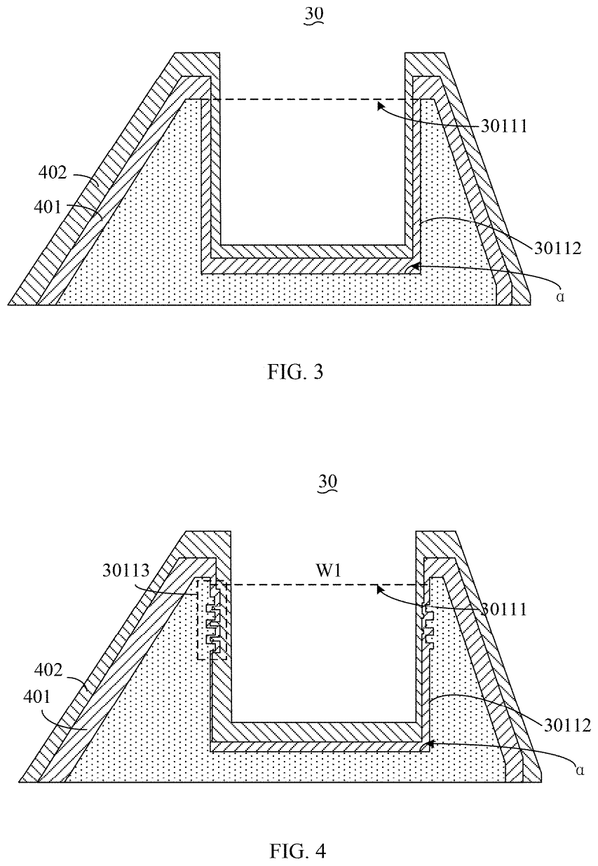

In some embodiments, as shown in FIG. 3, FIG. 3 is a schematic view of a first structure of a crack stop of a light emitting panel according to an embodiment of the present disclosure.

Wherein, the groove 3011 includes an opening portion 3011 and an inner cavity 30112 extending from the opening portion 30111 toward an inside of the blocking portion 301.

Wherein, a cross-sectional shape of the groove 3011 is any one of a square, a triangle, and a trapezoid. FIG. 3 only shows the case where the cross-sectional shape of the groove 3011 is square, as the same case with triangles or trapezoids, and details are not described herein again.

The groove 3011 may be formed by sputtering, deposition or inkjet printing (IJP) using a high-precision mask.

In some embodiments, the bottom of the inner cavity 30112 has at least one included angle α, and an angle of the included angle α is 60°-120°.

It can be understood that when the angle of the included angle α is less than 90°, the cross-sectional shape of the groove 3011 formed is triangle or trapezoid, and when the angle of the included angle α is greater than 90°, the cross-sectional shape of 3011 is trapezoidal. Preferably, the angle of the included angle α herein is 90°.

In some embodiments, as shown in FIG. 4, FIG. 4 is a schematic view of a second structure of a crack stop of a light emitting panel according to an embodiment of the present disclosure, a concave-convex structure 30113 is disposed on a sidewall of the inner cavity 3011, and the cross-sectional shape of the concave-convex structure 30113 is wavy or jagged.

It can be understood that the function of disposing the concave-convex structure 30113 on the sidewall of the inner cavity 3011 is the same as the principle of disposing the groove 3011, it is in order to generate an extended inflection point such that the crack is difficult to continue to extend.

The cross-sectional shape of the concave-convex structure may be jagged, as shown in FIG. 4, or may be wavy, and details are not described herein again. When the encapsulating layer 40 is subjected to CVD deposition, the first inorganic encapsulation layer 401 formed by deposition may be formed with respect to the concave-convex structure 30113 due to the presence of the concave-convex structure 30113 of the sidewall in the inner cavity 30112. Alternatively, for example, the second inorganic encapsulation layer 402 as shown, the second inorganic encapsulation layer 402 is directly covered on the concave-convex structure 30113, and it is not formed a concave-convex structure with respect to the concave-convex structure 30113.

In some embodiments, a horizontal opening length W1 of the opening portion 30111 is greater than 5 μm.

Specifically, the horizontal opening length W1 of the opening portion 30111 is defined here such that when the encapsulation layer 40 is subsequently prepared, the encapsulation layer 40 can be deposited into the grooves 3011 to avoid encapsulation failure.

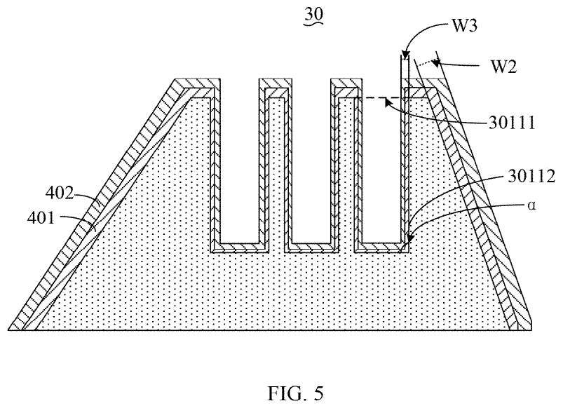

In some embodiments, as shown in FIG. 5, FIG. 5 is a schematic view of a third structure of a crack stop of a light emitting panel according to an embodiment of the present disclosure. The thickness of the encapsulation layer 40 disposed on the extension portion 301 is greater than the thickness of the encapsulation layer 40 disposed on the sidewall of the groove 3011.

Specifically, due to the presence of the included angle α in the cavity 30112 of the groove 3011, the encapsulation layer 40 is easily deposited on the extension portion 302 when the encapsulation layer 40 is deposited, while the encapsulation layer 40 is more difficultly deposited on the sidewalls of the grooves.

In some embodiments, a plurality of grooves 3011 are disposed on the blocking portion 301, and the plurality of grooves 3011 are spaced apart on the blocking portion 301.

Specifically, if the crack continues to extend through the inflection point at the intersection of the blocking portion 301 and the extending portion 302, there may be a case where the encapsulation fails. Therefore, the plurality of grooves 3011 may be disposed on the blocking portion 301 to reduce a probability of the crack extension, thereby the yield rate of the light panel 100 is increased.

It can be understood that since a high-precision mask is required for sputtering, deposition or inkjet printing in the process of forming the grooves 3011, thus gaps between adjacent formed grooves 3011 may be different, and lengths and shapes of the openings of the formed grooves 3011 may also be different.

A light emitting panel is provided in the embodiment of the present disclosure, including: a substrate 10 and an insulating layer 20 disposed on the substrate; a crack stop 30 including a blocking portion 301 and an extension portion 302, wherein the blocking portion 301 is disposed on at least one end of the insulating layer 20, and the extension portion 302 is extended onto the substrate 10; an encapsulation layer 40 covered the crack stop 30 and the substrate 10; wherein at least one groove 3011 is disposed on the blocking portion 301. The probability of crack extension is reduced by disposing one or more grooves 3011, and the cracks generated by cutting the light emitting panel 100 is prevented from extending to the display area by disposing the concave-convex structure 30113 on the sidewalls of the inner cavity 30112 in the grooves 3011, and the yield rate of the light-emitting panel is improved.

A light emitting panel is provided in the embodiment of the present disclosure also, including:

a substrate and an insulating layer disposed on the substrate;

a crack stop including a blocking portion and an extension portion, wherein the blocking portion is disposed on at least one end of the insulating layer, and the extension portion is extended onto the substrate;

an encapsulation layer covered the crack stop and the substrate; wherein

at least one groove is disposed on the blocking portion, the groove includes an opening portion and a cavity extending from the opening portion to the inside of the blocking portion, a retaining wall structure is further disposed on the insulating layer, the retaining wall structure is adjacent to the crack stop, and the encapsulating layer is covered the retaining wall structure.

Wherein, a bottom of the inner cavity has at least one included angle and an angle of the included angle is 60°-120°, a length of a horizontal opening of the opening portion is greater than 5 μm.

In the above embodiments, the descriptions of the various embodiments are different, and the details that are not described in a certain embodiment can be referred to the related descriptions of other embodiments.

The light emitting panel and the display device provided by the embodiments of the present disclosure are described in detail. The principles and embodiments of the present disclosure are described in the specific examples. The description of the above embodiments is only for helping understand the technical solutions and its core idea of present disclosure; it should be understood by those skilled in the art that they can still modify the technical solutions described in the above embodiments or equivalently replace some of the technical features; and an essence of these modifications or replacements in the corresponding technical solutions do not depart from the scope of the technical solutions of the embodiments of the present disclosure.

What is claimed is:

1. A light emitting panel, comprising:
a substrate and an insulating layer disposed on the substrate;
a crack stop comprising a blocking portion and an extension portion, wherein the blocking portion is disposed on at least one end of the insulating layer, and the extension portion is extended onto the substrate;
an encapsulation layer covered the crack stop and the substrate; wherein
at least one groove is disposed on the blocking portion.

2. The light emitting panel as claimed in claim 1, wherein the groove comprises an opening portion and an inner cavity extending from the opening portion toward an inside of the blocking portion.

3. The light emitting panel as claimed in claim 2, wherein a bottom of the inner cavity has at least one included angle and an angle of the included angle is 60-120°.

4. The light emitting panel as claimed in claim 3, wherein a concave-convex structure is disposed on a sidewall of the inner cavity, and a cross-sectional shape of the concave-convex structure is wavy or jagged.

5. The light emitting panel as claimed in claim 2, wherein a length of a horizontal opening of the opening portion is greater than 5 μm.

6. The light emitting panel as claimed in claim 1, wherein a thickness of the encapsulation layer disposed on the extension portion is greater than a thickness of the encapsulation layer disposed on the sidewall of the groove.

7. The light emitting panel as claimed in claim 6, wherein a cross-sectional shape of the groove is any one of a square, a triangle and a trapezoid.

8. The light emitting panel as claimed in claim 1, wherein a plurality of grooves are disposed on the blocking portion, the plurality of grooves are spaced apart on the blocking portion.

9. The light emitting panel as claimed in claim 1, wherein a retaining wall structure is further disposed on the insulating layer, the retaining wall structure is adjacent to the crack stop, and the encapsulating layer is covered the retaining wall structure.

10. A display device, comprising: a housing and a light emitting panel, the light emitting panel is disposed on the housing, the light emitting panel comprising:
a substrate and an insulating layer disposed on the substrate;
a crack stop comprising a blocking portion and an extension portion, the blocking portion disposed on at least one end of the insulating layer, the extension portion extended onto the substrate;
an encapsulation layer covered the crack stop and the substrate; wherein
at least one groove is disposed on the blocking portion.

11. The display device as claimed in claim 10, wherein the groove comprises an opening portion and an inner cavity extending from the opening portion toward an inside of the blocking portion.

12. The display device as claimed in claim 11, wherein a bottom of the inner cavity has at least one included angle and an angle of the included angle is 60°-120°.

13. The display device as claimed in claim 12, wherein a concave-convex structure is disposed on a sidewall of the inner cavity, and a cross-sectional shape of the concave-convex structure is wavy or jagged.

14. The display device as claimed in claim 11, wherein a length of a horizontal opening of the opening portion is greater than 5 μm.

15. The display device as claimed in claim 10, wherein a thickness of the encapsulation layer disposed on the extension portion is greater than a thickness of the encapsulation layer disposed on the sidewall of the groove.

16. The display device as claimed in claim 15, wherein a cross-sectional shape of the groove is any one of a square, a triangle and a trapezoid.

17. The display device as claimed in claim 10, wherein a plurality of grooves are disposed on the blocking portion, the plurality of grooves are spaced apart on the blocking portion.

18. The display device as claimed in claim 10, wherein a retaining wall structure is further disposed on the insulating layer, the retaining wall structure is adjacent to the crack stop, and the encapsulating layer is covered the retaining wall structure.

19. A light emitting panel, comprising:
a substrate and an insulating layer disposed on the substrate;
a crack stop comprising a blocking portion and an extension portion, wherein the blocking portion is disposed on at least one end of the insulating layer, and the extension portion is extended onto the substrate;
an encapsulation layer covered the crack stop and the substrate; wherein
at least one groove is disposed on the blocking portion, and the groove comprises an opening portion and an inner cavity extending from the opening portion toward an inside of the blocking portion, a retaining wall structure is further disposed on the insulating layer, the retaining wall structure is adjacent to the crack stop, and the encapsulating layer is covered the retaining wall structure.

20. The light emitting panel as claimed in claim 19, wherein a bottom of the inner cavity has at least one included angle and an angle of the included angle is 60°-120°, a length of a horizontal opening of the opening portion is greater than 5 μm.
